(19) United States
(12) Patent Application Publication
(10) Pub. No.: US 2020/0168714 A1
(43) Pub. Date: May 28, 2020

(54) SEMICONDUCTOR DEVICE AND METHOD FOR MANUFACTURING THE SAME

(71) Applicant: DENSO CORPORATION, Kariya-city (JP)

(72) Inventor: Youhei ODA, Kariya-city (JP)

(21) Appl. No.: 16/774,518

(22) Filed: Jan. 28, 2020

Related U.S. Application Data
(63) Continuation of application No. PCT/JP2018/029937, filed on Aug. 9, 2018.

(30) Foreign Application Priority Data
Aug. 21, 2017 (JP) 2017-158816
Aug. 21, 2017 (JP) 2017-158817

(51) Int. Cl. H01L 29/423; H01L 29/06; H01L 23/00

(52) U.S. Cl. CPC H01L 29/4236; H01L 24/45; H01L 29/0696

(57) ABSTRACT

A semiconductor device includes a semiconductor substrate; a semiconductor element disposed on a first surface of the semiconductor substrate; an insulation film, which is disposed on the first surface of the semiconductor substrate to cover the semiconductor element and has first contact holes exposing a region in the first surface of the semiconductor substrate, and second contact holes exposing the semiconductor element; a first electrode electrically connected to a region in the first surface of the semiconductor substrate through the first contact holes; and a second electrode electrically connected to the semiconductor element through the second contact hole. The insulation film has a first surface, which is flattened and opposite from the first surface of the semiconductor substrate. An interval between the first surface of the insulation film and the first surface of the semiconductor substrate is equal along a planer direction of the semiconductor substrate.

### CROSS REFERENCE TO RELATED APPLICATIONS

The present application is a continuation application of International Patent Application No. PCT/JP2018/029937 filed on Aug. 9, 2018, which designated the U.S. and claims the benefit of priority from Japanese Patent Application No. 2017-158816 filed on Aug. 21, 2017 and Japanese Patent Application No. 2017-158817 filed on Aug. 21, 2017. The entire disclosures of all of the above applications are incorporated herein by reference.

### TECHNICAL FIELD

The present disclosure relates to a semiconductor device and a method for manufacturing the semiconductor device.

### BACKGROUND

A semiconductor devices may include a temperature sensitive diode element, which is a diode element as a semiconductor element. The temperature sensitive diode element may be formed on a semiconductor substrate. More specifically, such a semiconductor device includes various types of regions formed on the semiconductor substrate, in order to allow an electric current flowing through the semiconductor substrate. These various types of regions are, for example, MOSFET (Metal Oxide Semiconductor Field Effect Transistor) elements, which may include P-type regions and N-type regions.

### SUMMARY

The present disclosure describes a semiconductor device, which includes a semiconductor element such as a diode element formed on a semiconductor substrate. Additionally, the present disclosure describes a method for manufacturing the semiconductor device.

### BRIEF DESCRIPTION OF THE DRAWINGS

FIG. 1 is a cross-sectional view of a semiconductor device according to a first embodiment.

FIG. 2A is a cross-sectional view illustrating a process for manufacturing the semiconductor device illustrated in FIG. 1.

FIG. 2B is a cross-sectional view illustrating a process for manufacturing the semiconductor device, which is subsequent to FIG. 2A.

FIG. 2C is a cross-sectional view illustrating a process for manufacturing the semiconductor device, which is subsequent to FIG. 2B.

FIG. 2D is a cross-sectional view illustrating a process for manufacturing the semiconductor device, which is subsequent to FIG. 2C.

FIG. 2E is a cross-sectional view illustrating a process for manufacturing the semiconductor device, which is subsequent to FIG. 2D.

FIG. 2F is a cross-sectional view illustrating a process for manufacturing the semiconductor device, which is subsequent to FIG. 2E.

FIG. 2G is a cross-sectional view illustrating a process for manufacturing the semiconductor device, which is subsequent to FIG. 2F.

FIG. 2H is a cross-sectional view illustrating a process for manufacturing the semiconductor device, which is subsequent to FIG. 2G.

FIG. 2I is a cross-sectional view illustrating a process for manufacturing the semiconductor device, which is subsequent to FIG. 2H.

FIG. 3 is a cross-sectional view of a semiconductor device according to a second embodiment.

FIG. 4A is a cross-sectional view illustrating a process for manufacturing the semiconductor device illustrated in FIG. 3.

FIG. 4B is a cross-sectional view illustrating a process for manufacturing the semiconductor device, which is subsequent to FIG. 4A.

FIG. 4C is a cross-sectional view illustrating a process for manufacturing the semiconductor device, which is subsequent to FIG. 4B.

FIG. 4D is a cross-sectional view illustrating a process for manufacturing the semiconductor device, which is subsequent to FIG. 4C.

FIG. 4E is a cross-sectional view illustrating a process for manufacturing the semiconductor device, which is subsequent to FIG. 4D.

FIG. 4F is a cross-sectional view illustrating a process for manufacturing the semiconductor device, which is subsequent to FIG. 4E.

FIG. 4G is a cross-sectional view illustrating a process for manufacturing the semiconductor device, which is subsequent to FIG. 4F.

FIG. 4H is a cross-sectional view illustrating a process for manufacturing the semiconductor device, which is subsequent to FIG. 4G.

FIG. 4I is a cross-sectional view illustrating a process for manufacturing the semiconductor device, which is subsequent to FIG. 4H.

FIG. 4J is a cross-sectional view illustrating a process for manufacturing the semiconductor device, which is subsequent to FIG. 4I.

FIG. 4K is a cross-sectional view illustrating a process for manufacturing the semiconductor device, which is subsequent to FIG. 4J.

FIG. 4L is a cross-sectional view illustrating a process for manufacturing the semiconductor device, which is subsequent to FIG. 4K.

FIG. 5 is a cross-sectional view of a semiconductor device according to a third embodiment.

FIG. 6 is a cross-sectional view of a semiconductor device according to a fourth embodiment.

FIG. 7 is a cross-sectional view of a semiconductor device according to a fifth embodiment.

FIG. 8 is a cross-sectional view of a semiconductor device according to a sixth embodiment.

FIG. 9A is a cross-sectional view illustrating a process for manufacturing the semiconductor device illustrated in FIG. 8.

FIG. 9B is a cross-sectional view illustrating a process for manufacturing the semiconductor device, which is subsequent to FIG. 9A.

FIG. 9C is a cross-sectional view illustrating a process for manufacturing the semiconductor device, which is subsequent to FIG. 9B.

FIG. 9D is a cross-sectional view illustrating a process for manufacturing the semiconductor device, which is subsequent to FIG. 9C.

FIG. 9E is a cross-sectional view illustrating a process for manufacturing the semiconductor device, which is subsequent to FIG. 9D.

FIG. 9F is a cross-sectional view illustrating a process for manufacturing the semiconductor device, which is subsequent to FIG. 9E.

FIG. 9G is a cross-sectional view illustrating a process for manufacturing the semiconductor device, which is subsequent to FIG. 9F.

FIG. 9H is a cross-sectional view illustrating a process for manufacturing the semiconductor device, which is subsequent to FIG. 9G.

FIG. 9I is a cross-sectional view illustrating a process for manufacturing the semiconductor device, which is subsequent to FIG. 9H.

FIG. 9J is a cross-sectional view illustrating a process for manufacturing the semiconductor device, which is subsequent to FIG. 9I.

FIG. 9K is a cross-sectional view illustrating a process for manufacturing the semiconductor device, which is subsequent to FIG. 9J.

FIG. 9L is a cross-sectional view illustrating a process for manufacturing the semiconductor device, which is subsequent to FIG. 9K.

FIG. 10 is a cross-sectional view of a semiconductor device according to other embodiments.

FIG. 11 is a cross-sectional view of a semiconductor device according to other embodiments.

FIG. 12 is a cross-sectional view of a semiconductor device according to other embodiments.

FIG. 13 is a cross-sectional view of a semiconductor device according to other embodiments.

FIG. 14 is a cross-sectional view of a semiconductor device according to other embodiments.

### DETAILED DESCRIPTION

On one surface of a semiconductor substrate, a temperature sensitive diode element through an insulation film may be formed, and the insulation film covering the temperature sensitive diode element may be formed. In the insulation film covering the temperature sensitive diode element, first contact holes for exposing a region formed in the one surface of the semiconductor substrate and second contact holes for exposing the temperature sensitive diode element may be formed.

On the insulation film covering the temperature sensitive diode element, a first electrode and a second electrode may be formed. The first electrode is electrically connected to a region formed in the one surface of the semiconductor substrate through the first contact holes, and the second electrode is electrically connected to the temperature sensitive diode element through the second contact holes.

Such a semiconductor device may be fabricated as follows. A temperature sensitive diode element is formed on one surface of a semiconductor substrate and, thereafter, an insulation film is formed as to cover the temperature sensitive diode element. Regions to be formed in the one surface of the semiconductor substrate are properly formed before or after the formation of the temperature sensitive diode element. A photoresist is placed on the insulation film. The photoresist is patterned by light exposure and photographic processing, and therefore the regions of the insulation film, where first contact holes and second contact holes are to be formed, are exposed from the photoresist. A first electrode, which is electrically connected to a region in the one surface of the semiconductor substrate through the first contact holes, is formed. A second electrode, which is electrically connected to the temperature sensitive diode element through the second contact holes, is formed. The semiconductor device is manufactured as described above.

However, with such a semiconductor device, when the insulation film has been formed as to cover the temperature sensitive diode element, the insulation film may be bulged at the portion covering the temperature sensitive diode element. The one surface of the insulation film, which is opposite from the one surface of the semiconductor substrate, is not a flattened surface. If the photoresist is placed on the insulation film, the photoresist may be bulged at the portion covering the temperature sensitive diode element, since the photoresist is formed along the one surface of the insulation film, which is opposite from the one surface of the semiconductor substrate.

If the photoresist is subjected to light exposure, the accuracy of the light exposure to the photoresist may be degraded. In cases of using a positive-type photoresist, for example, in performing light exposure to the photoresist, light from a light source is directed, through a photomask, to the portions of the photoresist which are on the regions where the first contact holes are to be formed, and to the portions of the photoresist which are on the regions where the second contact holes are to be formed. Light is directed to the un-bulged portion of the photoresist and light is directed to the bulged portion of the photoresist. For example, if the focal point is made coincident with the portions of the photoresist which are on the regions where the first contact holes are to be formed, the focal point may not be coincident with the portions of the photoresist which are on the regions where the second contact holes are to be formed. This may degrade the accuracy of the light exposure to the portions on the regions where the second contact holes are to be formed. Similarly, if the focal point is made coincident with the portions of the photoresist which are on the regions where the second contact holes are to be formed, the focal point may not be coincident with the portions of the photoresist which are on the regions where the first contact holes are to be formed. This may degrade the accuracy of the light exposure to the portions on the regions where the first contact holes are to be formed. Although the above description is given for describing a positive-type photoresist, the above description may also be applied to a negative-type photoresist.

If the accuracy of the light exposure to the photoresist is degraded, the accuracy of processing for the first and second contact holes may be degraded.

The diode element is placed in the semiconductor device through the insulation film. However, noises generated in the semiconductor substrate and the like may cause changes of the characteristics of the diode element, malfunctions of the diode element and the like. With such a semiconductor device, the accuracy of the detection with the diode element may be degraded. If the semiconductor device includes gate electrodes and is configured to control an electric current flowing through the semiconductor substrate by changing the gate voltage applied to the gate electrodes, the change of the gate voltage applied to the gate electrodes may tend to influence the diode element. This may degrade the accuracy of the detection with the diode element.

In one or more embodiments of the present disclosure, a semiconductor device may suppress degradation of the accuracy of processing for first and second contact holes, and a method for manufacturing the semiconductor may also suppress degradation of the accuracy of processing for first and second contact holes. Additionally, in one or more embodiments of the present disclosure, a semiconductor device may suppress degradation of the accuracy of detection with a diode element.

In a first aspect of the present disclosure, a semiconductor device includes: a semiconductor substrate having first surface; a semiconductor element formed on the first surface of the semiconductor substrate; an insulation film that is disposed on the first surface of the semiconductor substrate to cover the semiconductor element and the insulation film has a first contact hole for exposing a region in the first surface of the semiconductor substrate, and a second contact hole for exposing the semiconductor element; a first electrode electrically connected to a region in the first surface of the semiconductor substrate through the first contact hole; and a second electrode electrically connected to the semiconductor element through the second contact hole; in which the insulation film is flattened over the first surface opposite from the first surface of the semiconductor substrate and is configured such that an interval between the first surface and the first surface of the semiconductor substrate is equal along a planer direction of the semiconductor substrate.

The insulation film is flattened over the first surface. When a photoresist is placed on the insulation film, the photoresist is flattened over the first surface opposite from the insulation film. This may suppress the degradation of the accuracy of light exposure to the photoresist, which may suppress the degradation of the accuracy of processing for forming the first contact hole and the second contact hole using the photoresist as a mask.

In a second aspect of the present disclosure, a semiconductor device includes: a semiconductor substrate having first surface and having a semiconductor element formed thereon, the semiconductor element being configured to allow an electric current flowing through the semiconductor element; and a diode element formed on the first surface of the semiconductor substrate, in which on the first surface of the semiconductor substrate, a shield wiring portion maintained at a predetermined electric potential is formed, and the diode element is formed on the shield wiring portion.

The diode element is formed on the shield wiring portion which is maintained at a predetermined electric potential. This may suppress the degradation of the accuracy of the detection with the diode element due to noises in the semiconductor substrate, and the like.

In a third aspect of the present disclosure, a method for manufacturing a semiconductor device includes: preparing a semiconductor substrate having first surface; forming a semiconductor element on the first surface of the semiconductor substrate; forming an insulation film covering the semiconductor element on the first surface of the semiconductor substrate; forming a first contact hole for exposing a region in the first surface of the semiconductor substrate and further forming a second contact hole for exposing the semiconductor element; forming a first electrode electrically connected to a region in the first surface of the semiconductor substrate through the first contact hole; and forming a second electrode electrically connected to the semiconductor element through the second contact hole, in which a photoresist is placed on the insulation film and patterning the photoresist is patterned by light exposure and photographic processing, before the forming of the first contact hole and the second contact hole. The forming of the first contact hole and the second contact hole includes forming the first contact hole and the second contact hole at the same time, by using the photoresist as a mask and first surface of the insulation film that is opposite from the first surface of the semiconductor substrate is flattened before the placing of the photoresist.

Before the photoresist is placed, the insulation film is flattened at the first surface which is opposite from the first surface of the semiconductor substrate. When the photoresist is placed, the photoresist is flattened at the first surface which is opposite from the insulation film. This may suppress the degradation of the accuracy of light exposure to the photoresist, which may suppress the degradation of the accuracy of processing for forming the first contact hole and the second contact hole using the photoresist as a mask.

The following describes embodiments of the present disclosure with reference to the drawings. In the following respective embodiments, the same or equivalent parts are designated by the same reference signs.

### First Embodiment

The following describes a first embodiment with reference to the drawings. In the present embodiment, a semiconductor device including a MOSFET element formed on a semiconductor substrate is described.

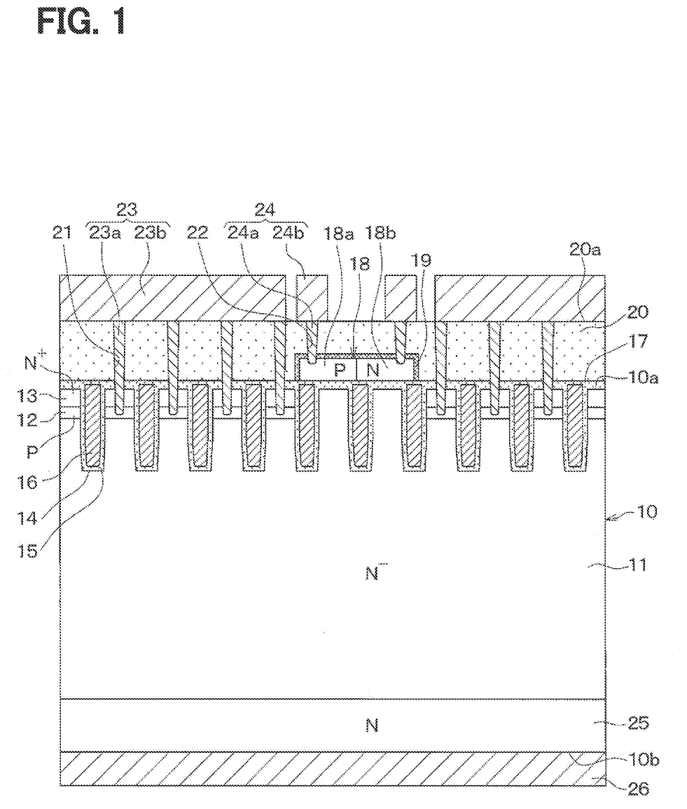

As illustrated in FIG. 1, the semiconductor device includes an N⁻-type semiconductor substrate 10 which functions as a drift layer 11. On the drift layer 11 (in other words, on a first surface 10a of the semiconductor substrate 10), a P-type base layer 12 is formed. On the base layer 12, an N⁺-type source layer 13 having a higher impurity concentration than that of the drift layer 11 is formed. In the present embodiment, on the drift layer 11, the base layer 12 and the source layer 13 in the mentioned order from the side closer to the drift layer 11 are formed. In the present embodiment, since the source layer 13 is formed as described above, the semiconductor substrate 10 includes the source layer 13 on the first surface 10a . In the present embodiment, the source layer 13 corresponds to a first-conduction-type layer.

In the semiconductor substrate 10, multiple trenches 14, each of which penetrates through the source layer 13 and the base layer 12 to reach the drift layer 11, are formed. The base layer 12 is divided by the multiple trenches 14. In the present embodiment, the multiple trenches 14 are formed at even intervals in a stripe shape, along a predetermined direction out of planer directions of the first surface 10a of the semiconductor substrate 10. In FIG. 1, the multiple trenches 14 are each formed along a depthwise direction, as viewed from the drawing of FIG. 1. In the present embodiment, the regions of the base layer 12, which come in contact with the trenches 14, correspond to channel regions.

In each of the trenches 14, a gate insulation film 15 formed to cover the wall surfaces of each trench 14, and a gate electrode 16 formed on the gate insulation film 15 are embedded. Thus, a trench gate configuration is formed. The gate electrodes 16 are electrically connected to a gate wiring, which is not illustrated, in a cross section different from that of FIG. 1, in which the gate wiring is formed on the first surface 10a of the semiconductor substrate 10. The gate electrodes 16 are configured such that a predetermined gate voltage from a gate control circuit (not illustrated) is applied to the gate electrodes 16. In the present embodiment, the gate insulation films 15 are formed by an oxide film or the like, and the gate electrodes 16 are formed by a polysilicon (which is referred to as a “Poly-Si”).

On the first surface 10a of the semiconductor substrate 10, a one-surface insulation film 17, which is formed by an oxide film or the like to cover the gate electrodes 16, is formed. In the present embodiment, on the one-surface insulation film 17, a temperature sensitive diode element 18 is formed. The temperature sensitive diode element 18 outputs a detection signal corresponding to heat generated from the operation of the MOSFET element. The temperature sensitive diode element 18 includes an anode region 18a formed by a P-type Poly-Si, and a cathode region 18b formed by an N-type Poly-Si. The anode region 18a and the cathode region 18b are connected to each other. An element protective film 19, which is formed by an oxide film or the like, is formed to cover the temperature sensitive diode element 18. In the present embodiment, the temperature sensitive diode element 18 corresponds to a semiconductor element.

On the one-surface insulation film 17, an inter-layer insulation film 20, which is formed by an oxide film or the like, is formed to cover the element protective film 19 (namely the temperature sensitive diode element 18). The inter-layer insulation film 20 is flattened over the first surface 20a, which is opposite from the first surface 10a of the semiconductor substrate 10. More specifically, the first surface 20a of the inter-layer insulation film 20 is flattened, such that the interval between the first surface 20a of the inter-layer insulation film 20 and the first surface 10a of the semiconductor substrate 10 is equal along a planer direction of the semiconductor substrate 10. In other words, regarding the interval between the first surface 20a and the first surface 10a of the semiconductor substrate 10, the inter-layer insulation film 20 is configured such that the interval in the portion covering the temperature sensitive diode element 18 is equal to the interval in the portion other than the portion covering the temperature sensitive diode element 18.

In the inter-layer insulation film 20, first contact holes 21 and second contact holes 22 are formed. The first contact holes 21 expose the source layer 13 and the base layer 12, and the second contact holes 22 expose the temperature sensitive diode element 18. More specifically, the multiple first contact holes 21 are formed to penetrate through the source layer 13 to reach the base layer 12, between the respective trenches 14 adjacent to each other. Thus, the source layer 13 is exposed from the side surfaces of the first contact holes 21, and the base layer 12 is exposed from the side surfaces and the bottom surfaces of the first contact holes 21. In addition, two second contact holes 22 are formed in which one of the holes is formed to expose the anode region 18a, while the other one is formed to expose the cathode region 18b.

On the inter-layer insulation film 20, a first upper-portion electrode 23, which is electrically connected to the source layer 13 and the base layer 12 through the first contact holes 21, is formed. In addition, a second upper-portion electrode 24, which is electrically connected to the temperature sensitive diode element 18 through the second contact holes 22, is formed. In the present embodiment, the first upper-portion electrode 23 corresponds to a first electrode, and the second upper-portion electrode 24 corresponds to a second electrode.

In the present embodiment, the first upper-portion electrode 23 includes a first embedded electrode portion 23a which is embedded in the first contact holes 21, and a first upper-layer electrode portion 23b which is placed on the inter-layer insulation film 20 and is electrically connected to the first embedded electrode portion 23a. Similarly, the second upper-portion electrode 24 includes a second embedded electrode portion 24a which is embedded in the second contact holes 22, and a second upper-layer electrode portion 24b which is placed on the inter-layer insulation film 20 and is electrically connected to the second embedded electrode portion 24a. In the present embodiment, the first and second embedded electrode portions 23a and 24a are formed by W (namely, tungsten). In other words, the first and second embedded electrode portions 23a and 24a are formed to be so-called W plugs. The first and second upper-layer electrode portions 23b and 24b are formed by Al (namely, aluminum) and the like.

On the side of the drift layer 11 which is opposite from the base layer 12 (namely, on the other surface 10b of the semiconductor substrate 10), an N-type drain layer 25 is formed. The N-type drain layer 25 has a higher impurity concentration than that of the drift layer 11. On the opposite side from the drift layer 11 across the drain layer 25, a lower-portion electrode 26 is formed. In other words, on the other surface 10b of the semiconductor substrate 10, the lower-portion electrode 26, which is electrically connected to the drain layer 25, is formed.

The semiconductor device according to the present embodiment has the structure. In the present embodiment, N⁺ type, N type and N⁻ type correspond to a first conduction type. P type and P⁺ type correspond to a second conduction type. The semiconductor substrate 10 according to the present embodiment includes the drain layer 25, the drift layer 11, the base layer 12 and the source layer 13.

The following describes processes for manufacturing the aforementioned semiconductor device with reference to the drawings. The processes for manufacturing the other surface 10b side (namely, the drain layer 25 side) of the semiconductor substrate 10 are not described in detail herein.

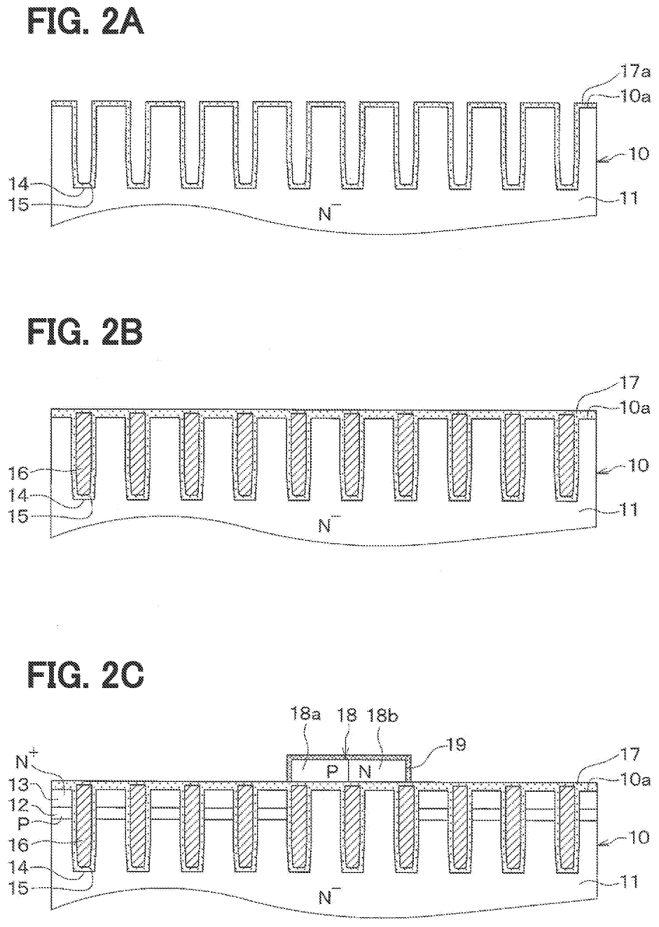

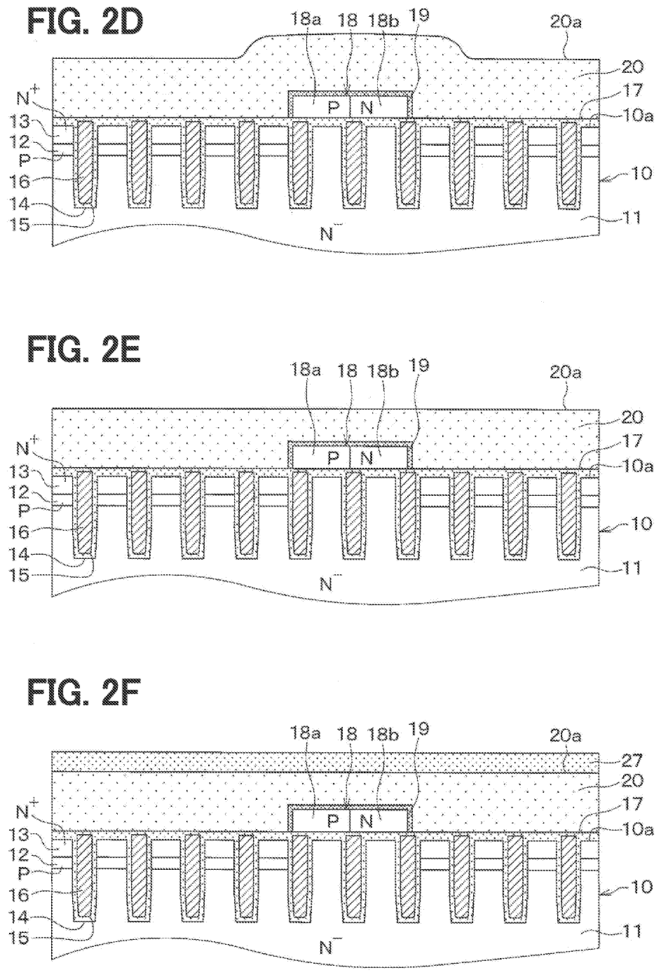

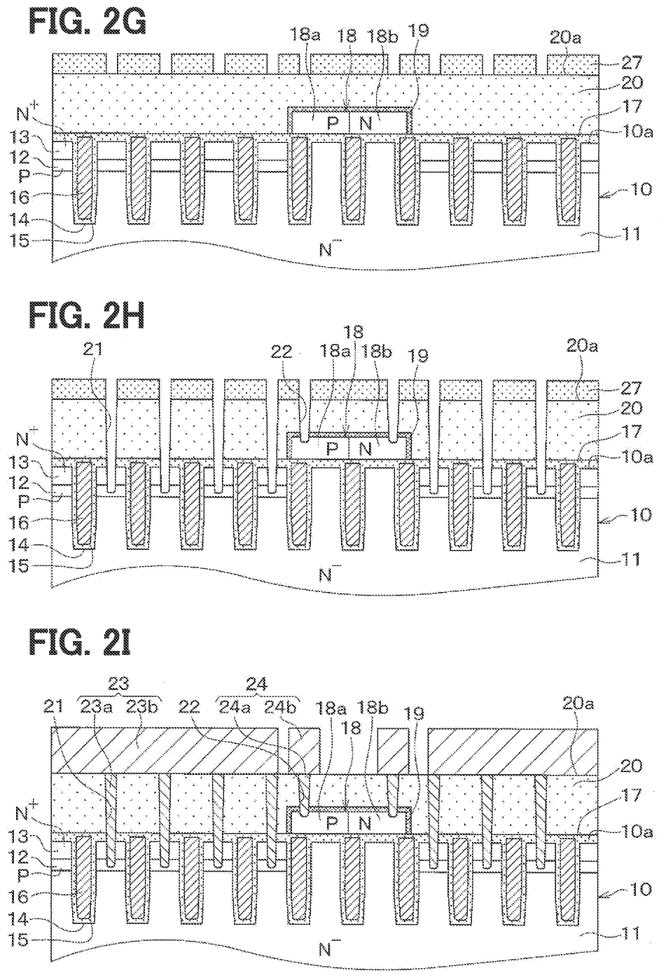

As illustrated in FIG. 2A, a semiconductor substrate 10 is prepared. Further, a mask is properly formed on first surface 10a of the semiconductor substrate 10. Multiple trenches 14 are formed in the semiconductor substrate 10 through dry etching or the like. Further, thermal oxidation or the like is performed to form gate insulation films 15 on the wall surfaces of the trenches 14 and to form a lower-side insulation film 17a forming a portion of an one-surface insulation film 17 on the first surface 10a of the semiconductor substrate 10.

As illustrated in FIG. 2B, a Poly-Si is deposited in such a way as to be embedded in the trenches 14, through a CVD (namely, Chemical Vapor Deposition) method or the like, and therefore gate electrodes 16 are formed. Further, in a cross section different from that of FIG. 2B, the Poly-Si deposited on the first surface 10a of the semiconductor substrate 10 is properly patterned to form a gate wiring which is electrically connected to the gate electrodes 16. Thereafter, thermal oxidation or the like is performed again, and therefore the one-surface insulation film 17 covering the gate electrodes 16 from the lower-side insulation film 17a is formed.

As illustrated in FIG. 2C, a Poly-Si is deposited on the one-surface insulation film 17 through a CVD method or the like and, thereafter, the Poly-Si is subjected to photoetching and the like, and therefore the outer shape of a temperature sensitive diode element 18 is formed. Further, a mask (not illustrated) is properly placed, and a P-type impurity and an N-type impurity are properly injected into the remaining Poly-Si through ion injection and are thermally diffused. This forms the temperature sensitive diode element 18 including an anode region 18a formed by a P-type Poly-Si, and a cathode region 18b formed by an N-type Poly-Si.

A P-type impurity and an N-type impurity are properly injected into the first surface 10a of the semiconductor substrate 10 and are thermally diffused, and therefore a base layer 12 and a source layer 13 are formed. Thereafter, thermal diffusion or the like is performed thereon, and therefore an element protective film 19 for protecting the temperature sensitive diode element 18 is formed.

In the present embodiment, the ion injection of impurities into the semiconductor substrate 10 is performed, after the deposition of the Poly-Si, which forms the temperature sensitive diode element 18. Therefore, the base layer 12 and the source layer 13 are not formed under the temperature sensitive diode element 18. However, the base layer 12 and the source layer 13 may be also formed over the entirety, thereafter, a Poly-Si, which forms the temperature sensitive diode element 18, may be deposited, and impurities may be injected into the Poly-Si, again, through ion injection or the like. Namely, the base layer 12 and the source layer 13 may be also formed under the temperature sensitive diode element 18. Thus, the region under the temperature sensitive diode element 18 may be effectively utilized, since the base layer 12 and the source layer 13 may be formed under the temperature sensitive diode element 18.

As illustrated in FIG. 2D, an inter-layer insulation film 20 is formed on the one-surface insulation film 17, through a CVD method or the like, in such a way as to cover the element protective film 19 (namely, the temperature sensitive diode element 18). Immediately after the formation of the inter-layer insulation film 20, the inter-layer insulation film 20 is in a state of having a level difference formed between the portion covering the temperature sensitive diode element 18 and the portion which does not cover the temperature sensitive diode element 18. In other words, the inter-layer insulation film 20 is in a state of having a level difference formed in the first surface 20a. The inter-layer insulation film 20 is in a state of being bulged at the portion covering the temperature sensitive diode element 18. In this process, the inter-layer insulation film 20 is formed such that the height of the first surface 20a in the portion other than the portion covering the temperature sensitive diode element 18 is higher than the height of the surface of the temperature sensitive diode element 18 from the first surface 10a of the semiconductor substrate 10. The surface of the temperature sensitive diode element 18 refers to the face of the temperature sensitive diode element 18 which is opposite from the first surface 10a of the semiconductor substrate 10.

As illustrated in FIG. 2E, the first surface 20a of the inter-layer insulation film 20 is flattened through a CMP (Chemical Mechanical Polishing) method or the like. More specifically, regarding the interval between the first surface 20a of the inter-layer insulation film 20 and the first surface 10a of the semiconductor substrate 10, the interval in the portion covering the temperature sensitive diode element 18 is equal to the interval in the portion other than the portion covering the temperature sensitive diode element 18.

As illustrated in FIG. 2F, a photoresist 27 is placed on the inter-layer insulation film 20. At this time, the first surface 20a of the inter-layer insulation film 20 has been flattened. Therefore, the photoresist 27 may be also placed as to be flattened. In the present embodiment, a positive-type photoresist 27 is placed on the inter-layer insulation film 20.

As illustrated in FIG. 2G, the photoresist 27 is patterned by light exposure and photographic processing to expose the regions of the inter-layer insulation film 20 where first contact holes 21 and second contact holes 22 are to be formed.

At the time of applying light exposure to the photoresist 27, a photomask (not illustrated) is placed on the photoresist 27. Then, light from a light source, after passing through the photomask, is directed to the portions of the photoresist 27 which are positioned on the regions where the first contact holes 21 are to be formed, and is directed to the portions of the photoresist 27 which are positioned on the regions where the second contact holes 22 are to be formed. At this time, the photoresist 27 is placed as to be flattened in the present embodiment. Therefore, the distance from the light source to the portions of the photoresist 27, which are positioned on the regions where the first contact holes 21 are to be formed, may be substantially equal to the distance from the light source to the portions of the photoresist 27, which are positioned on the regions where the second contact holes 22 are to be formed. This may suppress focal point deviation between light directed to the first portion of the photoresist 27 and light directed to the second portion of the photoresist 27. The first portion of the photoresist 27 is positioned on the regions where the first contact holes 21 are to be formed. The second portion of the photoresist 27 is positioned on the regions where the second contact holes 22 are to be formed. This may suppress the degradation of the accuracy of light exposure to the photoresist 27, and therefore may suppress the degradation of the accuracy of the processing of the photoresist 27.

As illustrated in FIG. 2H, dry etching or the like is performed using the photoresist 27 as a mask, and therefore the first contact holes 21 and the second contact holes 22 are formed at the same time. At this time, the degradation of the accuracy of the processing for the first contact holes 21 and the second contact holes 22 may be suppressed since the degradation of the accuracy of the processing of the photoresist 27 has been suppressed. In other words, the first contact holes 21 and the second contact holes 22 may be formed with higher accuracy.

As illustrated in FIG. 2I, the photoresist 27 is removed. The first upper-portion electrode 23 is formed. A second upper-portion electrode 24 is formed. The first upper-portion electrode 23 is electrically connected to the base layer 12 and the source layer 13, and the second upper-portion electrode 24 is electrically connected to the temperature sensitive diode element 18. In the present embodiment, at first, tungsten (W) is embedded in the first contact holes 21 and the second contact holes 22 through a CVD method or the like to form first and second embedded electrode portions 23a and 24a. Next, the tungsten film (W film) deposited on the first surface 20a of the inter-layer insulation film 20 is removed. Thereafter, a metal film formed by aluminum (Al) and the like is formed on the inter-layer insulation film 20, through a CVD method or the like. Further, the metal film formed thereon is patterned to form the first upper-layer electrode portion 23b and the second upper-layer electrode portion 24b. The first upper-layer electrode portion 23b is electrically connected to the first embedded electrode portion 23a. The second embedded electrode portion 24a is electrically connected to the second embedded electrode portion 24a. A semiconductor device according to the present embodiment is manufactured as described above.

In the present embodiment, the first surface 20a of the inter-layer insulation film 20 is flattened, after the formation of the inter-layer insulation film 20. Further, the photoresist 27 is placed on the first surface 20a of the inter-layer insulation film 20 which has been flattened. Therefore, the photoresist 27 is placed as to be flattened. Further, the distance from the light source to the portions of the photoresist 27, which are positioned on the regions where the first contact holes 21 are to be formed, may be substantially equal to the distance from the light source to the portions of the photoresist 27, which are positioned on the regions where the second contact holes 22 are to be formed. This may suppress focal point deviation between light directed to the first portion of the photoresist 27 and light directed to the second portion of the photoresist 27. This may suppress the degradation of the accuracy of light exposure. The first portion of the photoresist 27 is positioned on the regions where the first contact holes 21 are to be formed. The second portion of the photoresist 27 is positioned on the regions where the second contact holes 22 are to be formed.

Since the first contact holes 21 and the second contact holes 22 are formed using the photoresist 27 as a mask, the degradation of the accuracy of the processing for the first contact holes 21 and the second contact holes 22 may be suppressed.

In the present embodiment, the inter-layer insulation film 20 is configured such that the interval between the first surface 10a of the semiconductor substrate 10 and the first surface 20a in the portion other than the portion covering the temperature sensitive diode element 18 is equal to the interval between the first surface 10a of the semiconductor substrate 10 and the first surface 20a in the portion covering the temperature sensitive diode element 18. Even though the inter-layer insulation film 20 is formed to cover the temperature sensitive diode element 18, for example, the inter-layer insulation film 20 has a greater thickness, in comparison with cases where the interval between the first surface 10a of the semiconductor substrate 10 and the first surface 20a in the portion other than the portion covering the temperature sensitive diode element 18 is made shorter than the interval between the first surface 10a of the semiconductor substrate 10 and the first surface 20a in the portion covering the temperature sensitive diode element 18. Therefore, the inter-layer insulation film 20 placed between the gate electrodes 16 and the first upper-portion electrode 23 has a greater thickness, which may reduce parasitic capacitances. According to the present embodiment, noises generated by variations of the gate electric potential at the gate electrodes 16 may be easily absorbed by the inter-layer insulation film 20, which may suppress malfunctions of the semiconductor device and peripheral circuits placed near the semiconductor device.

### Second Embodiment

The following describes a second embodiment. In the present embodiment, the structure of the gate electrodes 16 is changed from that of the first embodiment, and the other structures are the same as those of the first embodiment and are not be described herein.

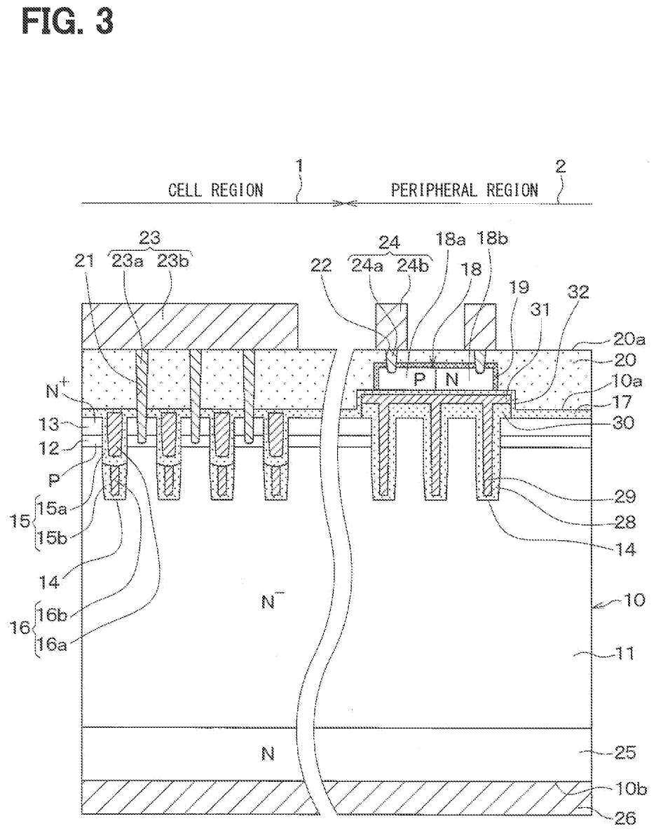

In the present embodiment, as illustrated in FIG. 3, a semiconductor device includes a cell region 1 where a MOSFET element is formed, and a peripheral region 2 different from the cell region 1. In this case, the peripheral region 2 is a different region from the cell region 1 and includes an outer edge region placed in such a way as to surround the cell region 1, and an intermediate region placed between adjacent cell regions 1. Namely, in the present embodiment, the peripheral region 2 is a region which may be positioned near the center of the semiconductor device, for example.

At first, the structure of the cell region 1 will be described. In the present embodiment, the cell region 1 has a trench gate configuration, which is a so-called split-gate configuration. More specifically, in each trench 14, a first gate insulation film 15a, a second gate insulation film 15b, a first gate electrode 16a and a second gate electrode 16b are placed. Within each trench 14, the first gate insulation film 15a and the first gate electrode 16a are placed in the opening portion side of the trench 14, and therefore an upper-stage side gate configuration is formed. The second gate insulation film 15b and the second gate electrode 16b are placed in the bottom portion side of the trench 14, and therefore a lower-stage side gate configuration is formed.

Each first gate electrode 16a is electrically connected to a gate wiring which is not illustrated, in a different cross section from that of FIG. 3. Thus, each first gate electrode 16a is adapted such that a predetermined gate voltage from a gate control circuit is applied thereto. Further, the respective second gate electrodes 16b are electrically connected to each other in a different cross section from that of FIG. 3 and are maintained at a predetermined electric potential. In the present embodiment, the second gate electrodes 16b are electrically connected to a first upper-portion electrode 23 and are maintained at the electric potential at the first upper-portion electrode 23, as will be described later.

The first gate electrodes 16a are formed up to a position deeper than the bottom portion of a base layer 12 from first surface 10a of the semiconductor substrate 10. Namely, the first gate electrodes 16a are placed in such a way as to form channels, which connect a source layer 13 and a drift layer 11 to each other in the base layer 12, when the gate voltage is applied to the first gate electrodes 16a. The first gate insulation films 15a are formed along the first gate electrodes 16a and are formed up to a position deeper than the bottom portion of the base layer 12 from the first surface 10a of the semiconductor substrate 10.

The second gate electrodes 16b are formed by the bottom portion of the upper-stage side gate configuration toward the bottom portions of the trenches 14. The second gate insulation films 15b are placed along the second gate electrodes 16b and are placed in the bottom portion sides of the trenches 14. The second gate insulation films 15b have a greater thickness than that of the first gate insulation films 15a. The first gate insulation films 15a are placed between the first gate electrodes 16a and the second gate electrodes 16b.

In the present embodiment, since the split-gate configuration is formed, occurrences of electric field concentrations at the bottom portions of the trenches 14 may be suppressed, and therefore the withstand voltage may be improved.

The structure of the peripheral region 2 is described. In the peripheral region 2, trenches 14 are formed, similarly to in the cell region 1. In each trench 14, a shield insulation film 28 formed as to cover the wall surfaces of each trench 14, and a shield electrode 29 formed on the shield insulation film 28 are embedded. The shield insulation films 28 and the shield electrodes 29, which are formed in the peripheral region 2, are similar to the second gate insulation films 15b and the second gate electrodes 16b, which are formed in the cell region 1. The shield electrodes 29 formed in the peripheral region 2 are electrically connected to the second gate electrodes 16b formed in the cell region 1, in a different cross section from that of FIG. 3.

On the first surface 10a of the semiconductor substrate 10, around the opening portions of the trenches 14, a lower-layer insulation film 30, which is connected to the shield insulation films 28, is formed. On the lower-layer insulation film 30, a shield wiring portion 31 as a lead wiring portion, which is electrically connected to the shield electrodes 29, is formed. The shield wiring portion 31 is electrically connected to the first upper-portion electrode 23 through a contact hole formed in the inter-layer insulation film 20, in a different cross section from that of FIG. 3. Thus, the shield electrodes 29 are maintained at the same electric potential as that at the first upper-portion electrode 23, through the shield wiring portion 31. The second gate electrodes 16b formed in the cell region 1 are electrically connected to the shield electrodes 29 formed in the peripheral region 2 and, therefore, are maintained at the electric potential at the first upper-portion electrode 23.

A wiring insulation film 32 is formed as to cover the shield wiring portion 31. A temperature sensitive diode element 18 is formed on the shield wiring portion 31 through the wiring insulation film 32. An element protective film 19 is formed as to cover the temperature sensitive diode element 18. In the present embodiment, the temperature sensitive diode element 18 is placed in the peripheral region 2. The temperature sensitive diode element 18 is electrically connected to a second upper-portion electrode 24, through second contact holes 22 formed in the inter-layer insulation film 20, similarly to in the first embodiment.

The semiconductor device according to the present embodiment has the aforementioned structure. A method for manufacturing the aforementioned semiconductor device is described.

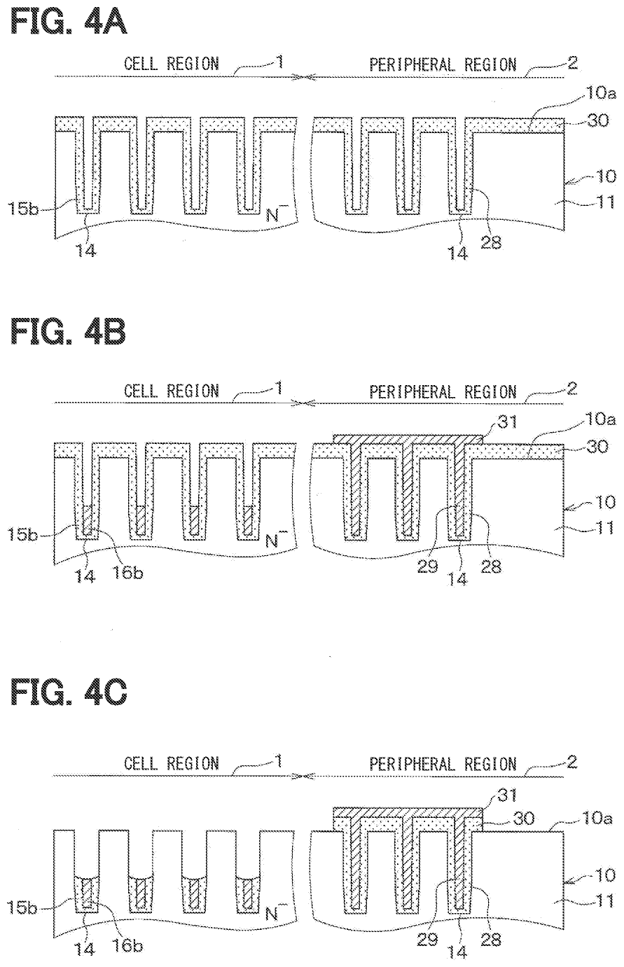

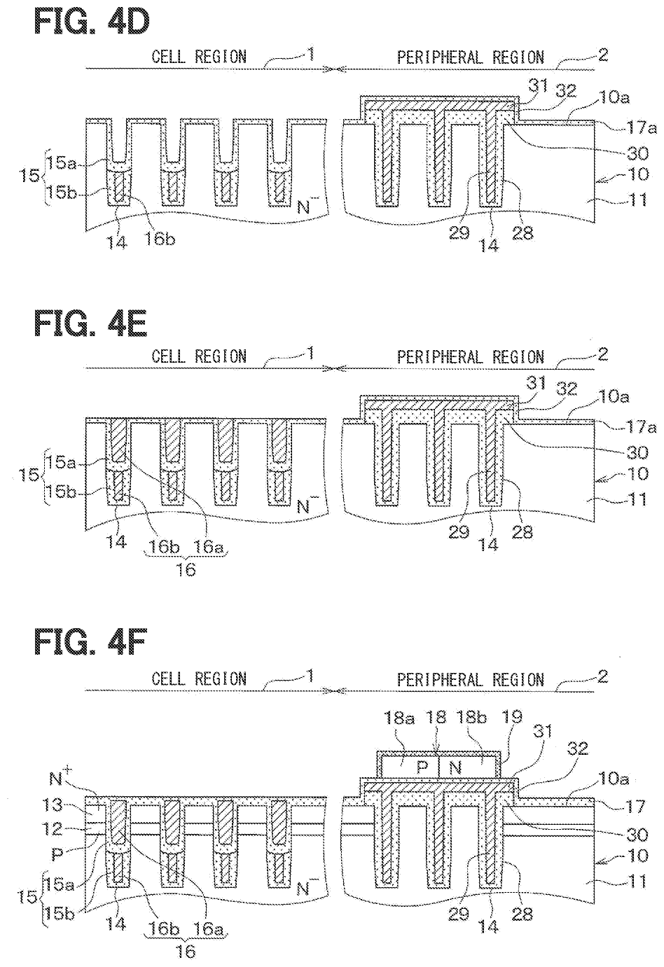

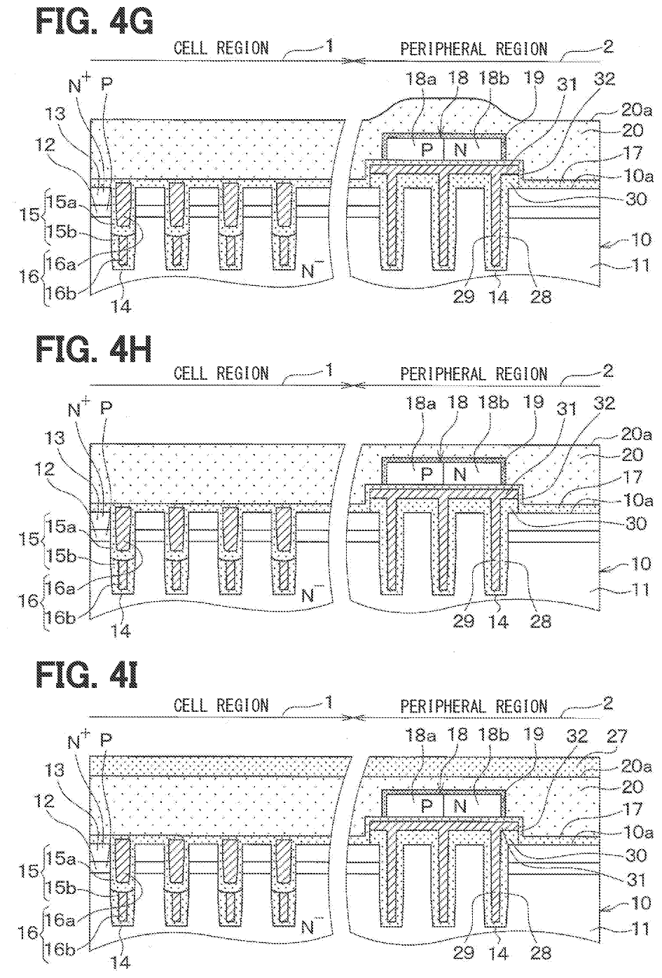

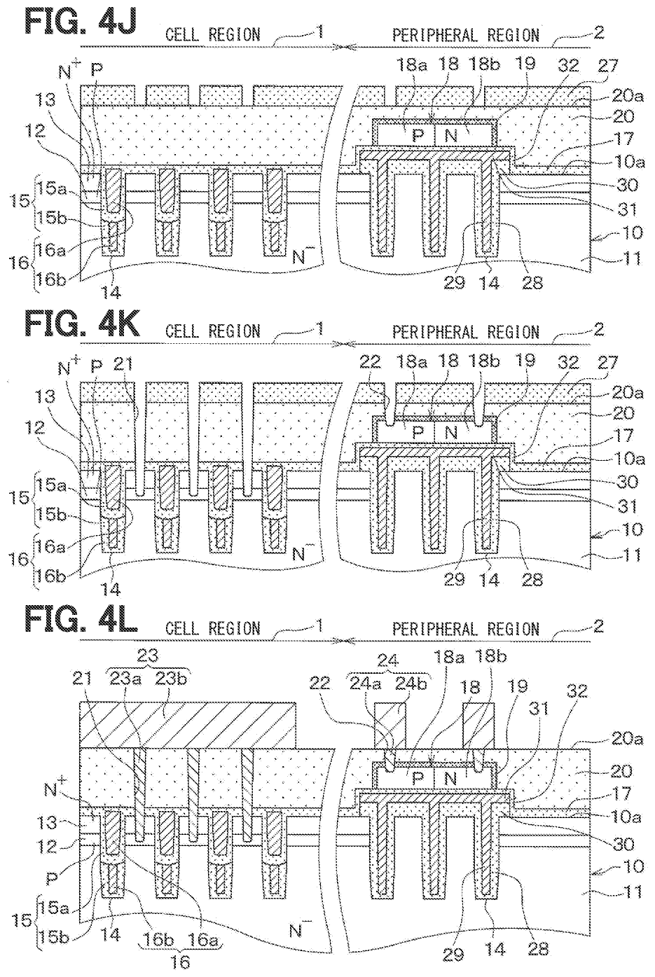

As illustrated in FIG. 4A, trenches 14 are formed in a semiconductor substrate 10 and, thereafter, second gate insulation films 15b and shield insulation films 28 are formed through thermal oxidation or the like. In this process, an insulation film is also formed on first surface 10a of the semiconductor substrate 10, and the insulation film forms a lower-layer insulation film 30 in a peripheral region 2.

As illustrated in FIG. 4B, a Poly-Si is deposited through a CVD method or the like, as to be embedded in the trenches 14. Further, second gate electrodes 16b are formed in the trenches 14 in a cell region 1, and shield electrodes 29 are formed in the trenches 14 in a peripheral region 2. Subsequently, a mask is properly formed and dry etching or the like is performed to pattern the Poly-Si formed on the first surface 10a of the semiconductor substrate 10 to form a shield wiring portion 31, in the peripheral region 2. Further, in the cell region 1, the Poly-Si placed on the first surface 10a of the semiconductor substrate 10 is removed, and the Poly-Si placed in the portions of the trenches 14 where first gate electrodes 16a are to be placed is removed.

As illustrated in FIG. 4C, a mask (not illustrated) is placed, and the insulation film formed on the first surface 10a of the semiconductor substrate 10 and in the portions of the trenches 14 where first gate insulation films 15a are to be formed is removed, in the cell region 1. Further, in the peripheral region 2, the insulation film formed on the first surface 10a of the semiconductor substrate 10 is removed, such that the lower-layer insulation film 30 is left under the shield wiring portion 31.

As illustrated in FIG. 4D, thermal oxidation or the like is performed, and therefore the first gate insulation films 15a is formed in the trenches 14 and a lower-layer insulation film 17a forming an one-surface insulation film 17 is formed on the first surface 10a of the semiconductor substrate 10, in the cell region 1. In the peripheral region 2, the lower-side insulation film 17a forming the one-surface insulation film 17 is formed on the first surface 10a of the semiconductor substrate 10 and, further, a wiring insulation film 32 covering the shield wiring portion 31 is formed.

As illustrated in FIG. 4E, a Poly-Si is deposited through a CVD method or the like as to be embedded in the trenches 14, and therefore the first gate electrodes 16a is formed. Further, a mask is properly formed and dry etching or the like is performed to properly pattern the Poly-Si formed on the first surface 10a of the semiconductor substrate 10, and therefore a gate wiring (not illustrated) is formed.

As illustrated in FIG. 4F, the same process as that of FIG. 2C is performed, and therefore a temperature sensitive diode element 18, a base layer 12 and a source layer 13 are formed. In the present embodiment, the temperature sensitive diode element 18 is formed on the shield wiring portion 31. Thereafter, thermal oxidation or the like is performed to form an element protective film 19 for protecting the temperature sensitive diode element 18 and, further, to form the one-surface insulation film 17 covering the first gate electrodes 16a.

As illustrated in FIGS. 4G to 4L, the same processes as those of FIGS. 2D to 2I are performed. As illustrated in FIG. 4G, an inter-layer insulation film 20 is formed on the one-surface insulation film 17, as to cover the element protective film 19 (namely, the temperature sensitive diode element 18). As illustrated in FIG. 4H, first surface 20a of the inter-layer insulation film 20 which is opposite from the first surface 10a of the semiconductor substrate 10 is flattened through a CMP method or the like. As illustrated in FIG. 4I, a photoresist 27 is placed on the inter-layer insulation film 20.

As illustrated in FIG. 4J, the photoresist 27 is patterned by light exposure and photographic processing, as to expose the regions of the inter-layer insulation film 20 where first contact holes 21 and second contact holes 22 are to be formed. As illustrated in FIG. 4K, dry etching or the like is performed using the photoresist 27 as a mask, and therefore the first contact holes 21 and the second contact holes 22 are formed at the same time. As illustrated in FIG. 4L, a first upper-portion electrode portion 23 electrically connected to the base layer 12 and the source layer 13 is formed A second upper-portion electrode portion 24 electrically connected to the temperature sensitive diode element 18 is formed. A semiconductor device according to the present embodiment is manufactured as described above.

In the present embodiment, the temperature sensitive diode element 18 is placed in the peripheral region 2. The temperature sensitive diode element 18 is placed on the shield wiring portion 31, which is maintained at a predetermined electric potential. This may provide the same effects as those of the first embodiment, while suppressing malfunctions of the temperature sensitive diode element 18 due to variations of the gate electric potential at the first gate electrodes 16a.

### Third Embodiment

The following describes a third embodiment. In the present embodiment, the gate configuration according to the second embodiment is combined with the first embodiment, and the other structures are the same as those of the first embodiment and are not be described herein.

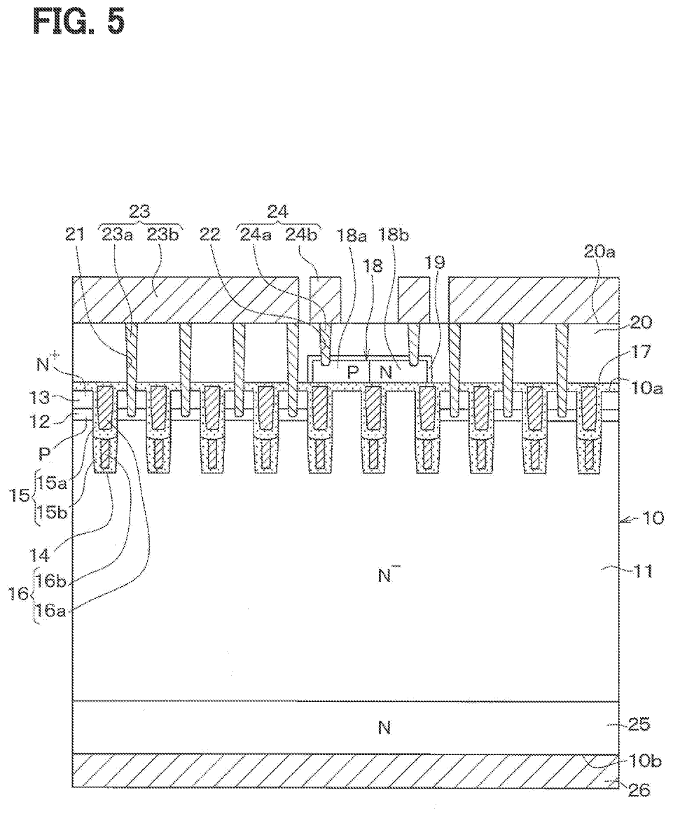

In the present embodiment, as illustrated in FIG. 5, a trench gate configuration, which is formed to be a split-gate configuration, is provided, similarly to the second embodiment. Within each trench 14, a first gate insulation film 15a and a first gate electrode 16a are placed in the opening portion side of the trench 14,and therefore an upper-stage side gate configuration is formed. A second gate insulation film 15b and a second gate electrode 16b are placed in the bottom portion side of the trench 14, and therefore a lower-stage side gate configuration is formed. A temperature sensitive diode element 18 is placed on the split-gate configuration.

The temperature sensitive diode element 18 may be placed on the split-gate configuration. With the semiconductor device according to the present embodiment, the same effects as those of the first embodiment may be provided when a first surface 20a of an inter-layer insulation film 20 is flattened.

The semiconductor device according to the present embodiment may be fabricated by properly combining the manufacturing methods described in the first and second embodiments.

### Fourth Embodiment

The following describes a fourth embodiment. In the present embodiment, a peripheral region is provided in the first embodiment, and the other structures are the same as those of the first embodiment and are not be described herein.

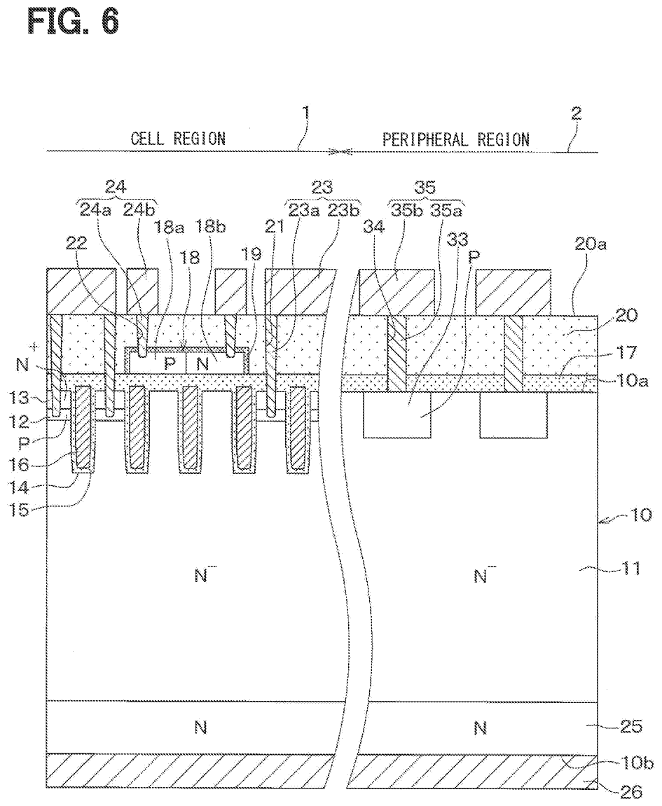

In the present embodiment, as illustrated in FIG. 6, a cell region 1 and a peripheral region 2 are provided and a temperature sensitive diode element 18 is placed in the cell region 1. A one-surface insulation film 17 positioned under the temperature sensitive diode element 18 has a greater thickness than that of the first embodiment. More specifically, the one-surface insulation film 17 is provided with an enough thickness to suppress malfunctions of the temperature sensitive diode element 18 due to variations of the gate voltage applied to gate electrodes 16, noises from a semiconductor substrate 10 and the like. For example, the one-surface insulation film 17 has a thickness of 300 nm. In other words, the one-surface insulation film 17 is provided with a thickness that keeps the characteristics of the temperature sensitive diode element unchanged due to variations of the gate voltage applied to gate electrodes 16, noises from the semiconductor substrate 10, and the like.

In the present embodiment, the gate electrodes 16 are formed as to partially protrude from a first surface 10a of the semiconductor substrate 10. For example, the gate electrodes 16 protrude from the first surface 10a by about 200 nm. The one-surface insulation film 17 is formed to have a greater thickness than the amount of the protrusion of the gate electrodes 16. The one-surface insulation film 17 is formed as to cover the portions of the gate electrodes 16, which protrude from the first surface 10a of the semiconductor substrate 10. In this case, the thickness of the one-surface insulation film 17 refers to the interval between the first surface 10a of the semiconductor substrate 10 and the surface of the one-surface insulation film 17 which is opposite from the semiconductor substrate 10.

The peripheral region 2 is formed to have a multiple-ring configuration including multiple P-type guard rings 33, which have a higher impurity concentration than that of a base layer 12, in the first surface 10a of the semiconductor substrate 10. The one-surface insulation film 17 and an inter-layer insulation film 20 are also formed in the peripheral region 2.

In the one-surface insulation film 17 and the inter-layer insulation film 20 formed in the peripheral region 2, third contact holes 34, which expose the guard rings 33, are formed. On the inter-layer insulation film 20, a third upper-portion electrode 35 is formed. The third upper-portion electrode 35 is electrically connected to the guard rings 33 through the third contact holes 34. The third upper-portion electrode 35 has the same structure as those of the first upper-portion electrode 23 and the second upper-portion electrode 24, and includes a third embedded electrode portion 35a and a third upper-layer electrode portion 35b.

In the present embodiment, the one-surface insulation film 17 in the cell region 1 is provided with a greater thickness in order to suppress malfunctions of the temperature sensitive diode element 18. The one-surface insulation film 17 in the peripheral region 2 is provided with the same thickness as that of the one-surface insulation film 17 in the cell region 1. In the present embodiment, the one-surface insulation film 17 is formed to have a greater thickness over the entirety, rather than only under the temperature sensitive diode element 18. The one-surface insulation film 17 is flattened over the one surface in the opposite side from the semiconductor substrate 10.

The one-surface insulation film 17 may have a greater thickness, in order to suppress malfunctions of the temperature sensitive diode element 18 due to variations of the gate voltage applied to gate electrodes 16. The one-surface insulation film 17 is flattened over the entirety of the cell region 1 and the peripheral region 2. At the time of formation of the temperature sensitive diode element 18 in the process in FIG. 2C, the formation of a level difference in the Poly-Si when the Poly-Si has been deposited is suppressed. This may suppress the degradation of the accuracy of processing for performing photo etching on the Poly-Si, which enables forming the temperature sensitive diode element 18 with higher accuracy.

Similar to the first embodiment, the first surface 20a of the inter-layer insulation film 20 is flattened. This may suppress the degradation of the accuracy of processing for the third contact holes 34.

### Fifth Embodiment

The following describes a fifth embodiment. In the present embodiment, the second and fourth embodiments are combined, and the other structures are the same as those of the first embodiment and are not be described herein.

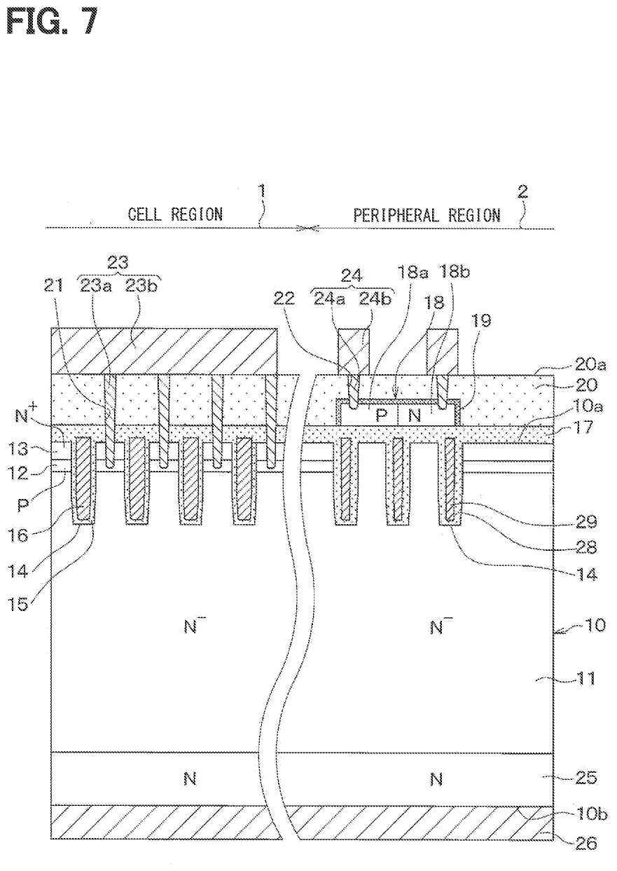

In the present embodiment, as illustrated in FIG. 7, trenches 14 are also formed in a peripheral region 2. A shield insulation film 28 and a shield electrode 29 are embedded in each trench 14. The shield electrodes 29 are formed as to partially protrude from first surface 10a of a semiconductor substrate 10, similarly to gate electrodes 16. For example, the shield electrodes 29 protrude from the first surface 10a by about 200 nm. In the present embodiment, no shield wiring portion 31 is formed in the peripheral region 2. Although not illustrated in particular, in a different cross section from that of FIG. 7, the shield electrodes 29 are connected to a lead wiring portion formed on the first surface 10a of the semiconductor substrate 10, and this lead wiring portion is connected to a first upper-portion electrode 23 and, thus, is maintained at the electric potential at the first upper-portion electrode 23.

An one-surface insulation film 17 is formed as to cover the shield electrodes 29 and the portions of the gate electrodes 16 which protrude from the first surface 10a of the semiconductor substrate 10. Similar to the fourth embodiment, the one-surface insulation film 17 has a thickness of 300 nm in the present embodiment. A temperature sensitive diode element 18 is placed on the shield electrodes 29 through the one-surface insulation film 17. The cell region 1 has the same structure as that of the fourth embodiment.

Even when the temperature sensitive diode element 18 is placed on the shield electrodes 29 through the one-surface insulation film 17, malfunctions of the temperature sensitive diode element may be suppressed since the one-surface insulation film 17 has a greater thickness.

### Sixth Embodiment

The following describes a sixth embodiment. In the present embodiment, the structure of a cell region 1 is changed from that in the second embodiment, and the other structures are the same as those of the first embodiment and are not be described herein.

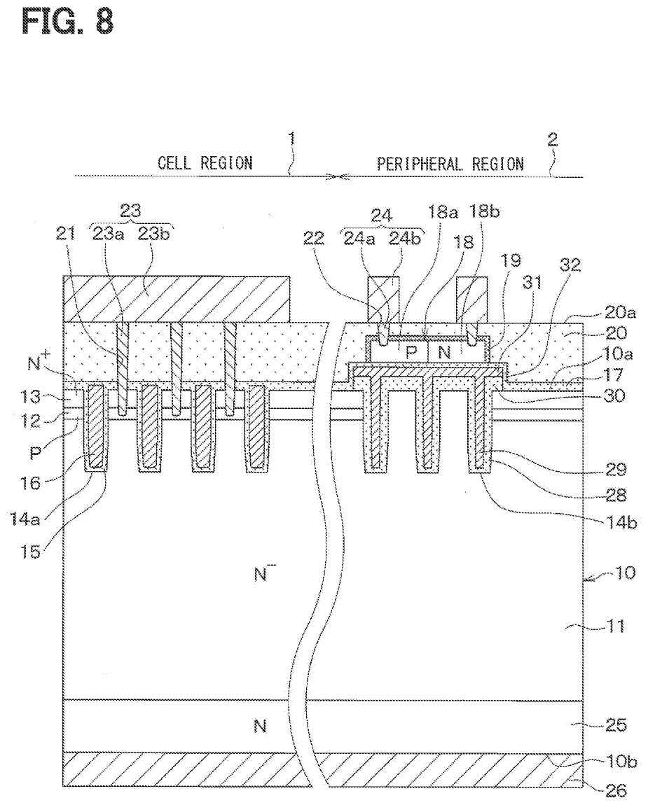

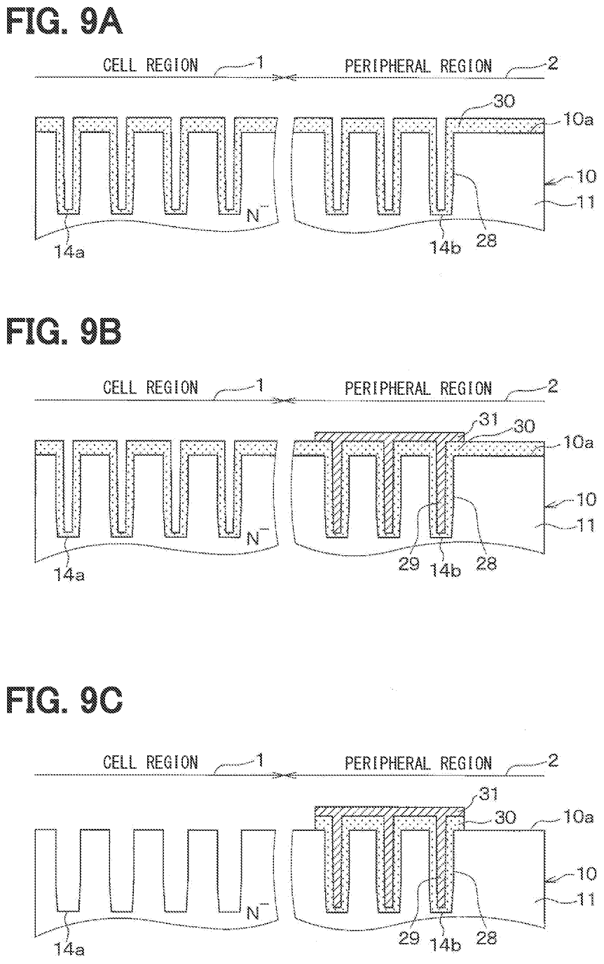

In the present embodiment, as illustrated in FIG. 8, trenches formed in a cell region 1 are referred to as first trenches 14a, while trenches formed in a peripheral region 2 are referred to as second trenches 14b. In the present embodiment, the second trenches 14b correspond to shield trenches.

The cell region 1 has a trench gate configuration having the same structure as that of the first embodiment. In each first trench 14a, a gate insulation film 15 formed as to cover the wall surfaces of the first trench 14a, and a gate electrode 16 formed on the gate insulation film 15 are embedded.

As similar to the second embodiment, in the peripheral region 2, a shield insulation film 28 and a shield electrode 29 are embedded in each second trench 14b. The shield insulation film 28 is formed as to cover the wall surfaces of the second trench 14b, and the shield electrode 29 is formed on the shield insulation film 28. In the present embodiment, the shield electrodes 29 are electrically connected to a first upper-portion electrode 23 and are at the same electric potential as that at the first upper-portion electrode 23.

The shield insulation films 28 according to the present embodiment are formed to have a greater thickness than that of the gate insulation films 15, since the shield electrodes 29 are maintained at a predetermined electric potential, in order to improve the withstand voltage. In other words, the gate insulation films 15 are provided with a smaller thickness than that of the shield insulation film 28, such that an inversion layer is formed in a base layer 12, when a predetermined gate voltage is applied to the gate electrodes 16.

Similar to the second embodiment, in the peripheral region 2, a shield wiring portion 31, which is electrically connected to the shield electrodes 29, is formed on a lower-layer insulation film 30. The shield wiring portion 31 is electrically connected to the first upper-portion electrode 23, in a different cross section from that of FIG. 8. The shield electrodes 29 are maintained at the same electric potential as that at the first upper-portion electrode 23, through the shield wiring portion 31. On the surface and the side surfaces of the shield wiring portion 31, a wiring insulation film 32 formed by an oxide film or the like is formed as to cover the shield wiring portion 31.

The semiconductor device according to the present embodiment has the aforementioned structure. The following describes processes for manufacturing the aforementioned semiconductor device with reference to the drawings.

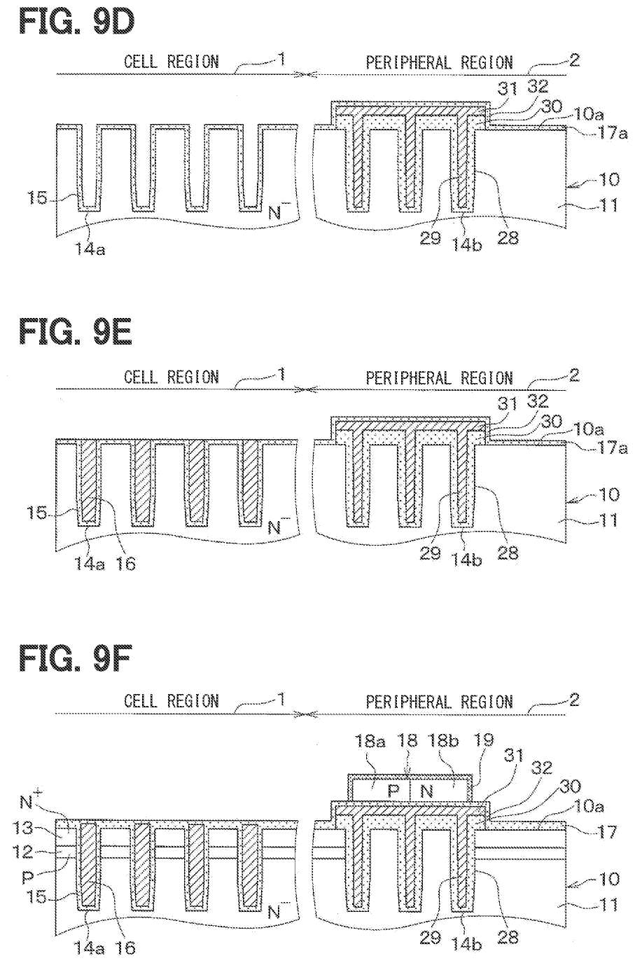

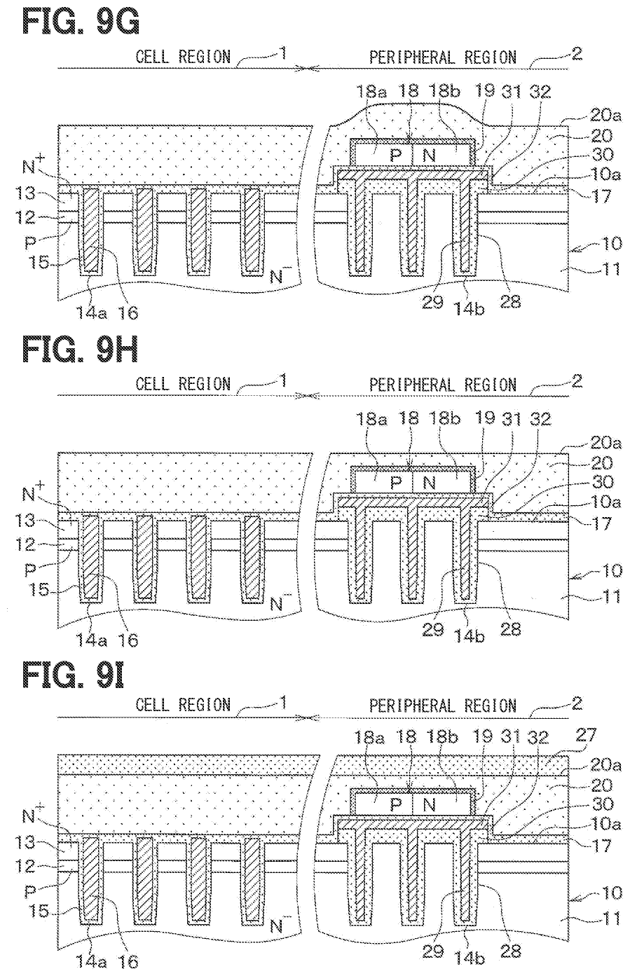

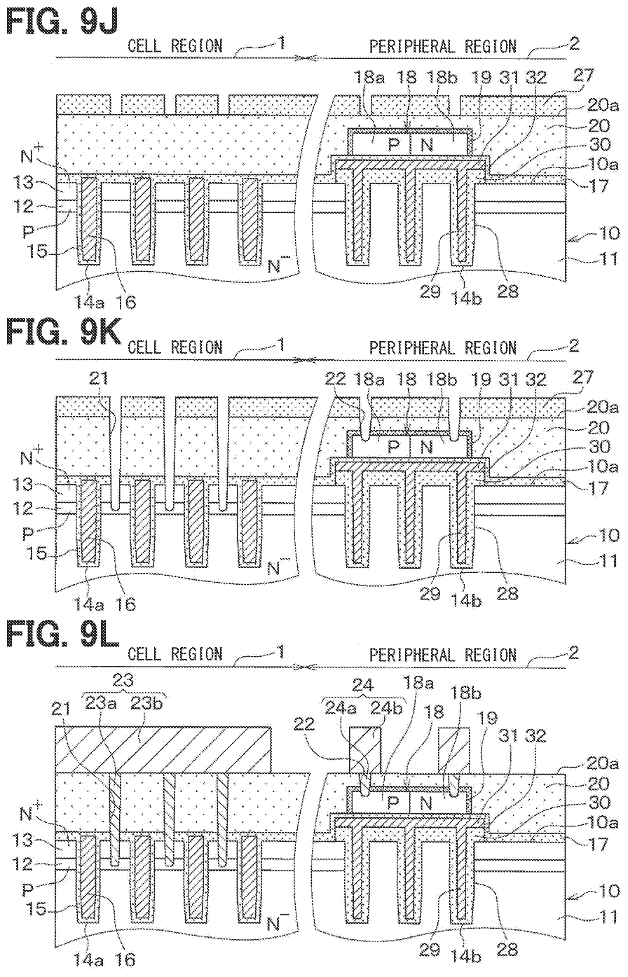

As illustrated in FIG. 9A, a semiconductor substrate 10 provided with first trenches 14a and second trenches 14b is prepared. Further, thermal oxidation or the like is performed to form shield insulation films 28 in the second trenches 14b and to form a lower-layer insulation film 30 around the opening portions of the second trenches 14b. In this process, an insulation film is also formed in the first trenches 14a, and on first surface 10a of the semiconductor substrate 10 at the other portions than the peripheries of the opening portions of the second trenches 14b.

As illustrated in FIG. 9B, a Poly-Si is deposited as to be embedded in the second trenches 14b, through a CVD method or the like. This results in formation of shield electrodes 29 in the second trenches 14b through the shield insulation films 28 in a peripheral region 2. A mask (not illustrated) is properly formed, and dry etching or the like is performed to pattern the Poly-Si formed on the first surface 10a of the semiconductor substrate 10, and therefore a shield wiring portion 31 is formed in the peripheral region 2. In a cell region 1, the Poly-Si placed on the first surface 10a of the semiconductor substrate 10, and the Poly-Si placed in the first trenches 14a are removed.

As illustrated in FIG. 9C, a mask (not illustrated) is placed, and the insulation film formed in the process in FIG. 9A is removed, in the cell region 1. In the peripheral region 2, the insulation film formed on the first surface 10a of the semiconductor substrate 10 is removed, such that the lower-layer insulation film 30 placed under the shield wiring portion 31 is remained.

As illustrated in FIG. 9D, thermal oxidation or the like is performed. In the cell region 1, gate insulation films 15 are formed in the first trenches 14a, and a lower-side insulation film 17a forming a lower-layer side portion of an one-surface insulation film 17 is formed on the first surface 10a of the semiconductor substrate 10. In the peripheral region 2, the lower-side insulation film 17a forming the lower-layer side portion of the one-surface insulation film 17 is formed on the first surface 10a of the semiconductor substrate 10, and a wiring insulation film 32 covering the shield wiring portion 31 is formed on the first surface 10a.

As illustrated in FIG. 9E, a Poly-Si is deposited through a CVD method or the like as to be embedded in the respective first trenches 14a, and therefore gate electrodes 16 are formed in the cell region 1. A mask is properly formed, and dry etching or the like is performed to properly pattern the Poly-Si formed on the first surface 10a of the semiconductor substrate 10, and therefore a gate wiring (not illustrated) is formed. The Poly-Si formed in the peripheral region 2 is removed.

As illustrated in FIG. 9F, a Poly-Si is deposited on the shield wiring portion 31 through a CVD method or the like and, thereafter, photoetching and the like are performed on the Poly-Si, and therefore the outer shape of a temperature sensitive diode element 18 is formed. A mask (not illustrated) is properly placed, and a P-type impurity and an N-type impurity are properly injected into the remaining Poly-Si through ion injection and are thermally diffused. This forms the temperature sensitive diode element 18 including an anode region 18a formed by a P-type Poly-Si, and a cathode region 18b formed by an N-type Poly-Si.

A P-type impurity and an N-type impurity are properly injected into the first surface 10a of the semiconductor substrate 10 and are thermally diffused, and therefore a base layer 12 and a source layer 13 are formed. In the present embodiment, the ion injection of impurities is performed after the formation of the shield wiring portion 31 and the like. The base layer 12 and the source layer 13 are not formed under the shield wiring portion 31. Thereafter, thermal diffusion or the like is performed thereon, and therefore an element protective film 19 for protecting the temperature sensitive diode element 18 is formed, and the one-surface insulation film 17 from the lower-side insulation film 17a is formed.

As illustrated in FIGS. 9G to 9L, the same processes as those of FIGS. 2D to 2I are performed. As illustrated in FIG. 9G, an inter-layer insulation film 20 is formed on the one-surface insulation film 17, as to cover the element protective film 19 (namely, the temperature sensitive diode element 18). As illustrated in FIG. 9H, first surface 20a of the inter-layer insulation film 20 which is opposite from the first surface 10a of the semiconductor substrate 10 is flattened through a CMP method or the like. As illustrated in FIG. 9I, a photoresist 27 is placed on the inter-layer insulation film 20.

As illustrated in FIG. 9J, the photoresist 27 is patterned by light exposure and photographic processing, as to expose the regions of the inter-layer insulation film 20 where first contact holes 21 and second contact holes 22 are to be formed. As illustrated in FIG. 9K, dry etching or the like is performed using the photoresist 27 as a mask, and therefore the first contact holes 21 and the second contact holes 22 are formed at the same time. As illustrated in FIG. 9L, a first upper-portion electrode portion 23 electrically connected to the base layer 12 and the source layer 13 is formed, and a second upper-portion electrode portion 24 electrically connected to the temperature sensitive diode element 18 is formed. A semiconductor device according to the present embodiment is manufactured as described above.

In the present embodiment, the temperature sensitive diode element 18 is formed on the shield wiring portion 31, and the shield wiring portion 31 is electrically connected to the first upper-portion electrode 23 and is maintained at a predetermined electric potential. This may suppress the degradation of the accuracy of the detection with the temperature sensitive diode element 18 due to noises in the semiconductor substrate 10 and the like. More specifically, the degradation of the accuracy of the detection with the temperature sensitive diode element 18 due to noises caused by changes of the gate voltage applied to the gate electrodes 16 may be suppressed, for example.

In the present embodiment, the second trenches 14b are formed in the peripheral region 2, and the shield electrodes 29 electrically connected to the shield wiring portion 31 is placed within these second trenches 14b. This may improve the withstand voltage in the peripheral region 2.

In the present embodiment, the peripheral region 2 is a region, which may be positioned near the center of the semiconductor device. Therefore, the semiconductor device may be configured such that the peripheral region 2 is near the center of the semiconductor device, and the temperature sensitive diode element 18 may be placed in the peripheral region 2 in order to improve the temperature detection sensitivity.

Other Embodiments

The present disclosure has been described regarding to the embodiments, but it should be understood that the present disclosure may not be limited to these embodiments and configurations. The present disclosure also encompasses various modified examples and changes falling within equivalent ranges. In addition, various combinations and aspects, and other combinations and aspects further including only one element or more or less than in addition thereto are also encompassed within the scope and spirit of the present disclosure.

For example, although, in the respective embodiments, cases where the first conduction type is N type and the second conduction type is P type have been described, semiconductor devices such that the first conduction type is P type and the second conduction type is N type also may be provided. The conduction types of the respective portions having been described in the respective embodiments may be reversed.

In the respective embodiments, the semiconductor element formed on the semiconductor substrate 10 may be also a Zener diode element, for example, rather than a temperature sensitive diode element 18.

In the respective embodiments, a P-type collector layer may be also provided, instead of the drain layer 25. An IGBT (namely, Insulated Gate Bipolar Transistor) element may be formed on the semiconductor substrate 10. In addition, a semiconductor device having a super-junction configuration including an N-type column region and a P-type column region which are placed on a drain layer 25 may be provided.

In the respective embodiments, a lateral-type semiconductor device, which includes a drain layer 25 formed on the surface-layer portion of the drift layer 11 and is configured to flow an electric current in a planer direction of the semiconductor substrate 10, may be provided.

In the respective embodiments, a planer-type gate configuration instead of a trench-type gate configuration may be employed. For example, the same effects may be provided, by flattening the first surface 20a of the inter-layer insulation film 20 in the first embodiment. With this structure, the degradation of the accuracy of processing for the first contact holes 21 and the second contact holes 22 due to the gate configuration formed on the first surface 10a of the semiconductor substrate 10 may be suppressed. In the sixth embodiment, even with such a planer-type gate configuration, the degradation of the accuracy of the detection with the temperature sensitive diode element 18 may be suppressed by placing the temperature sensitive diode element 18 on the shield wiring portion 31.

In the respective embodiments, barrier metals, which are formed by Ti, TiN or the like, may also be formed on the wall surfaces of the first contact holes 21 and the second contact holes 22. Such barrier metals are formed through sputtering or the like, before the formation of the first and second embedded electrode portions 23a and 24a, for example.

In the respective embodiments, in the first upper-portion electrode 23, the first embedded electrode portion 23a and the first upper-layer electrode portion 23b may be formed by the same material and, for example, they may be formed by Al. Similarly, in the second upper-portion electrode 24, the second embedded electrode portion 24a and the second upper-layer electrode portion 24b may be formed by the same material and, for example, they may be formed by Al.

In the respective embodiments, the source layer 13 may be also selectively formed on the surface-layer portion of the base layer 12. The first surface 10a of the semiconductor substrate 10 may be also configured to have a base layer 12 and a source layer 13. In this case, the first contact holes 21 are not necessarily required to be formed up to a larger depth than that of the first surface 10a of the semiconductor substrate 10, since only the base layer 12 and the source layer 13 are required to be exposed. The first contact holes 21 are required to be formed only as to expose the base layer 12 and the source layer 13, from the first surface 10a of the semiconductor substrate 10.

In the respective embodiments, the temperature sensitive diode element 18 may be also configured to include multiple anode regions 18a and cathode regions 18b, which are placed in the temperature sensitive diode element 18.

In the respective embodiments, the photoresist 27 for forming the first contact holes 21 and the second contact holes 22 may also be a negative type.

In the second embodiment, the shield wiring portion 31 may be also provided in the cell region 1, and the temperature sensitive diode element 18 may be placed on the shield wiring portion 31 in the cell region 1.

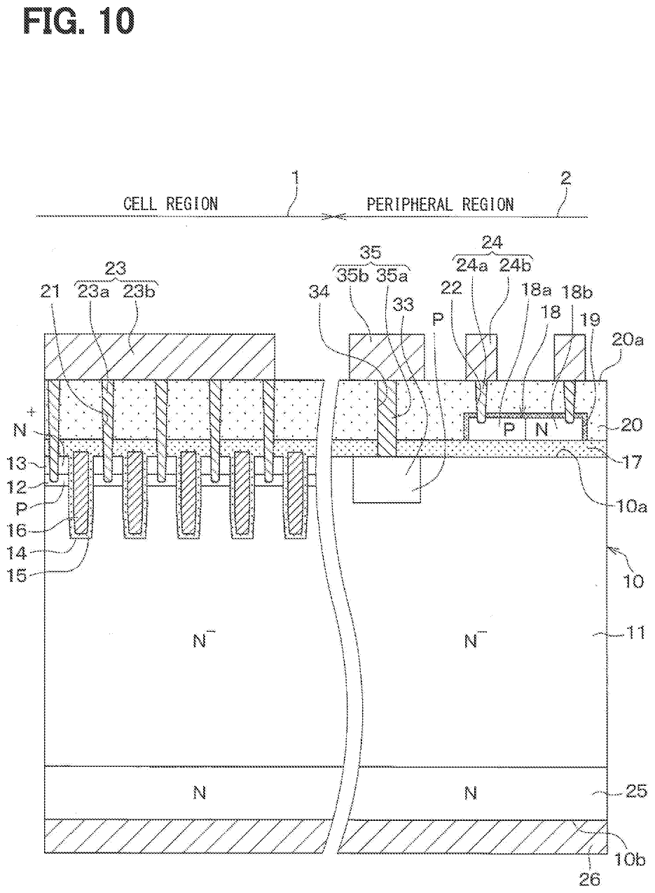

In the fourth embodiment, as illustrated in FIG. 10, the temperature sensitive diode element 18 may be also placed in the peripheral region 2. The gate electrodes 16 may be also configured not to be placed just beneath the temperature sensitive diode element 18. Even with this structure, malfunctions of the temperature sensitive diode element 18 due to variations of the gate voltage applied to the gate electrodes 16 may occur. Therefore, such malfunctions of the temperature sensitive diode element 18 may be suppressed by making the one-surface insulation film 17 to have a greater thickness, as similar to the fourth embodiment.

In the fifth embodiment, although not illustrated in particular, the shield electrodes 29 may be also configured not to be placed just beneath the temperature sensitive diode element 18.

In the aforementioned fourth embodiment, the one-surface insulation film 17 is not required to be flattened. In this case, the gate electrodes 16 from being exposed, by forming the one-surface insulation film 17 such that it covers at least the portions of the gate electrodes 16 which protrude from the first surface 10a of the semiconductor substrate 10. The occurrence of protrusions of portions from the one surface of the one-surface insulation film 17 which is opposite from the semiconductor substrate 10 may be suppressed. When the temperature sensitive diode element 18 is formed in the process of FIG. 2C, even if the process for flattening the one-surface insulation film 17 is not performed, the formation of a level difference in the Poly-Si, when the Poly-Si has been deposited, may be suppressed. Similarly, in the fifth embodiment, the one-surface insulation film 17 is not required to be flattened.

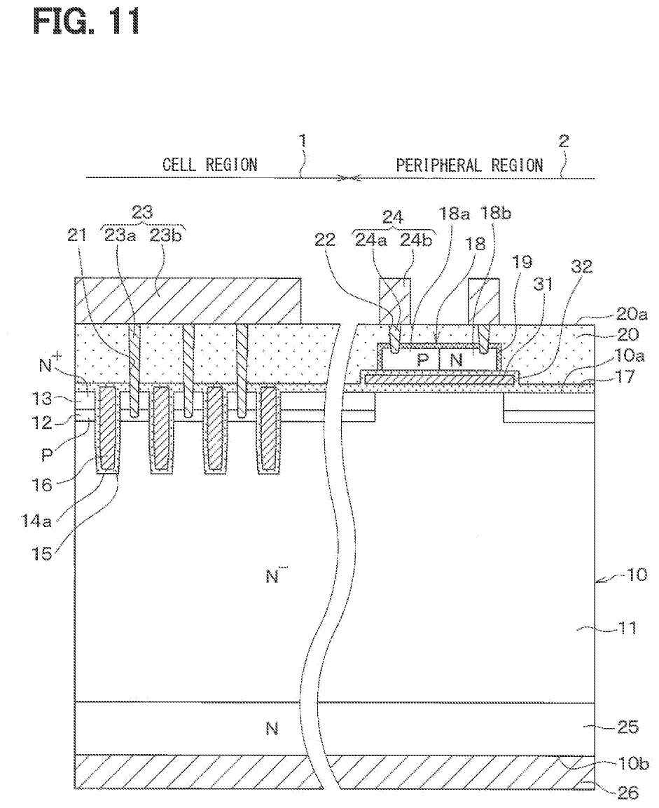

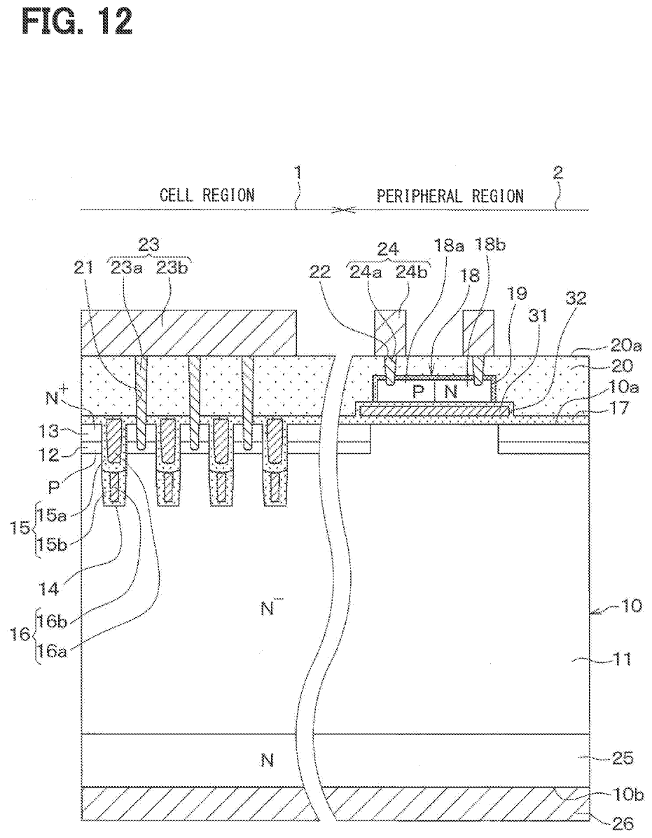

In the sixth embodiment, as illustrated in FIG. 11, no second trench 14b may be formed, and no shield electrode 29 may be formed. Similarly, in the second embodiment, as illustrated in FIG. 12, no trench 14 may be formed in the peripheral region 2, and no shield electrode 29 may be formed. In these structures, similarly, the shield wiring portion 31 is connected to the first upper-portion electrode 23, in a different cross section from that of FIG. 11 or 12.

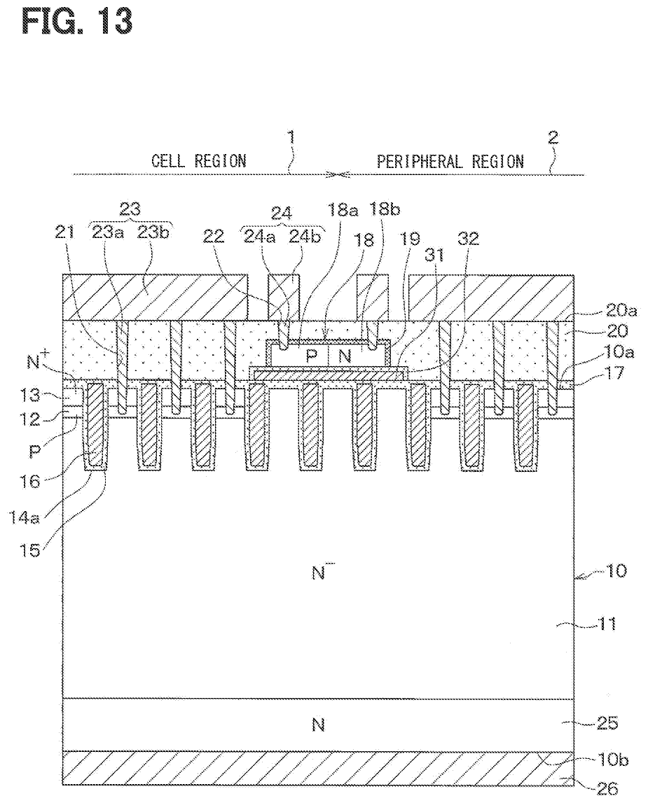

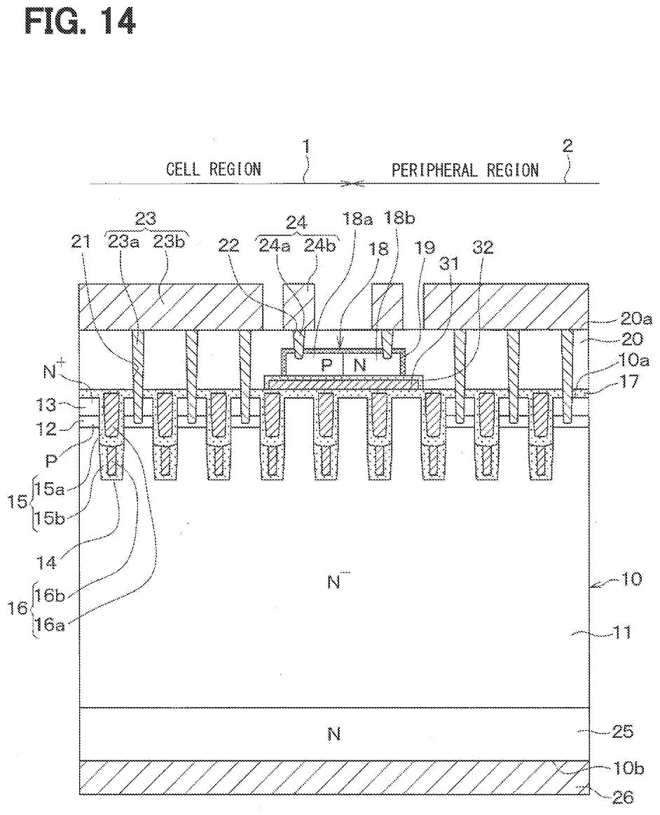

In the sixth embodiment, as illustrated in FIG. 13, neither second trench 14b nor shield electrode 29 may be formed, and the same trench gate configuration may be provided in the cell region 1 and the peripheral region 2. The shield wiring portion 31 may be formed on the first trenches 14a. In this structure, similarly, the shield wiring portion 31 is connected to the first upper-portion electrode 23, in a different cross section from that of FIG. 13. In the second embodiment, similarly, as illustrated in FIG. 14, the same trench gate configuration may be provided in the cell region 1 and the peripheral region 2, and no shield electrode 29 may be formed. The shield wiring portion 31 is connected to the second gate electrodes 16b, in a different cross section from that of FIG. 14. In these structures, since the same trench gate configuration is provided in the cell region 1 and the peripheral region 2, the temperature sensitive diode element 18 may be placed either in the cell region 1 or in the peripheral region 2.

With the structures in FIGS. 11 to 14, the degradation of the accuracy of the detection with the temperature sensitive diode element 18 may be suppressed since the temperature sensitive diode element 18 is formed on the shield wiring portion 31, which is maintained at a predetermined electric potential.

In the second and sixth embodiments, the shield electrodes 29 and the shield wiring portion 31 may be formed by different materials. For example, the shield wiring portion 31 may be formed by Al or the like.

What is claimed is:

1. A semiconductor device comprising:
a semiconductor substrate having a first surface;
a semiconductor element disposed on the first surface of the semiconductor substrate;
an insulation film disposed on the first surface of the semiconductor substrate to cover the semiconductor element, the insulation film having
a first contact hole for exposing a region in the first surface of the semiconductor substrate, and
a second contact hole for exposing the semiconductor element;
a first electrode electrically connected to the region in the first surface of the semiconductor substrate through the first contact hole; and
a second electrode electrically connected to the semiconductor element through the second contact hole,
wherein the insulation film has a first surface of the insulation film, which is flattened and opposite from the first surface of the semiconductor substrate,
wherein an interval between the first surface of the insulation film and the first surface of the semiconductor substrate is equal along a planer direction of the semiconductor substrate,
wherein the semiconductor device includes:
a cell region; and
a peripheral region different from the cell region, wherein the cell region includes:
a drift layer of a first conduction type;
a base layer of a second conduction type disposed on the drift layer;
a first-conduction-type layer disposed on a surface-layer portion of the base layer, and having a higher impurity concentration than an impurity concentration of the drift layer;
a gate insulation film disposed on a channel region, the channel region being a surface of a portion of the base layer positioned between the first-conduction-type layer and the drift layer; and
a gate electrode disposed on the gate insulation film and configured to be applied by a predetermined gate voltage,
wherein the semiconductor substrate has a one-surface insulation film disposed on the first surface of the semiconductor substrate, and the one-surface insulation film has a first surface, which is flattened and opposite to the first surface of the semiconductor substrate, over the cell region and the peripheral region,
wherein the semiconductor element is disposed on the one-surface insulation film,
wherein the one-surface insulation film has a thickness, which keeps a characteristic of the semiconductor element from unchanged by the gate voltage applied to the gate electrode, and the one-surface insulation film has a uniform thickness over the cell region and the peripheral region,
wherein the peripheral region has a trench,
wherein the trench has a shield insulation film disposed inside the trench,
wherein the trench has a shield electrode disposed on the shield insulation film, and the shield electrode is maintained at a predetermined electric potential,
wherein the shield electrode has a portion of the shield electrode protruding from the first surface of the semiconductor substrate, and
wherein the one-surface insulation film covers the portion of the shield electrode.

2. The semiconductor device according to claim 1,
wherein the cell region has a trench, which penetrates through the first-conduction-type layer and the base layer to reach the drift layer,
wherein the gate insulation film and the gate electrode are disposed in the trench,
wherein the gate electrode has a portion of the gate electrode protruding from the first surface of the semiconductor substrate, and
wherein the one-surface insulation film covers the portion of the gate electrode.

3. A semiconductor device comprising:
a semiconductor substrate having a first surface and a semiconductor element, which is disposed on the semiconductor substrate; and
a diode element disposed on the first surface of the semiconductor substrate,
wherein the semiconductor substrate has a shield wiring portion, which is maintained at a predetermined electric potential and is disposed on the first surface of the semiconductor substrate,
wherein the diode element is disposed on the shield wiring portion,
wherein the semiconductor substrate has a shield trench, which is disposed under the shield wiring portion, and
wherein the shield trench has a shield electrode, which is electrically connected to the shield wiring portion through a shield insulation film.

4. The semiconductor device according to claim 3,
wherein the semiconductor substrate includes:
a drift layer of a first conduction type;
a base layer of a second conduction type disposed on the drift layer;
a first-conduction-type layer disposed on a surface-layer portion of the base layer, and having a higher impurity concentration than an impurity concentration of the drift layer;
a gate configuration including
a gate insulation film disposed on a region including a channel region, the channel region being a surface of a portion of the base layer positioned between the first-conduction-type layer and the drift layer, and
a gate electrode disposed on the gate insulation film; and
an electrode electrically connected to the base layer and the first-conduction-type layer, and
wherein the shield wiring portion is connected to the electrode.
